(19) United States
(12) Patent Application Publication
(10) Pub. No.: US 2025/0254908 A1
(43) Pub. Date: Aug. 7, 2025

(54) SEMICONDUCTOR DEVICE

(71) Applicant: Samsung Electronics Co., Ltd., Suwon-si (KR)

(72) Inventor: HYUNGSOON JANG, Suwon-si (KR)

(21) Appl. No.: 18/813,378

(22) Filed: Aug. 23, 2024

(30) Foreign Application Priority Data
Feb. 1, 2024 (KR) 10-2024-0015850

(51) Int. Cl. H01L 29/417; H01L 21/762; H01L 21/84; H01L 23/528; H01L 27/12

(52) U.S. Cl. CPC H10D 30/6219; H01L 21/76264; H01L 23/5286; H10D 86/011; H10D 86/215

(57) ABSTRACT

A semiconductor device may include a transistor, a semiconductor structure spaced apart from the transistor in a first direction, a device isolation layer surrounding the transistor and the semiconductor structure. The semiconductor structure may include a lower pattern, an intermediate pattern on the lower pattern, and an upper pattern on the intermediate pattern, the device isolation layer may include a first portion in contact with the transistor and a second portion in contact with the semiconductor structure, and a level of an upper surface of the lower pattern may be higher than a level of a lower surface of the second portion of the device isolation layer.

### CROSS-REFERENCE TO RELATED APPLICATIONS

This U.S. non-provisional patent application claims priority under 35 U.S.C. § 119 to Korean Patent Application No. 10-2024-0015850 filed on Feb. 1, 2024, in the Korean Intellectual Property Office, the entire contents of which are hereby incorporated by reference.

### BACKGROUND OF THE INVENTION

The inventive concept relates to a semiconductor device, and more particularly, relates to a semiconductor device including a semiconductor structure.

Metal-oxide-semiconductor field effect transistors (MOSFETs) are widely used semiconductor devices in very large scale integrated circuits. As the semiconductor devices become increasingly integrated with the advancement of the electronic industry, the MOSFETs have been scaled down in accordance with the reduced design rule of the semiconductor devices. Operating characteristics of the semiconductor devices may be deteriorated by the reduction in size of the MOSFETs. Accordingly, various methods for forming semiconductor devices which have excellent performance while overcoming limitations by the high integration have been studied.

### SUMMARY

Aspects of the inventive concept provide to a semiconductor device with improved electrical characteristics and reliability.

A semiconductor device according to some embodiments of the inventive concept may include a transistor, a semiconductor structure spaced apart from the transistor in a first direction, a device isolation layer surrounding the transistor and the semiconductor structure. The semiconductor structure comprises an active device that includes a lower pattern, an intermediate pattern on the lower pattern, and an upper pattern on the intermediate pattern, the device isolation layer includes a first portion having a top surface and a bottom surface and being in contact with the transistor, and a second portion having a top surface and a bottom surface and being in contact with the semiconductor structure, and a level of a top boundary of the lower pattern is higher than a level of the bottom surface of the second portion of the device isolation layer.

A semiconductor device according to some embodiments of the inventive concept may include a transistor; a semiconductor structure spaced apart from the transistor in a horizontal direction and a device isolation layer surrounding the transistor and the semiconductor structure. The semiconductor structure comprises an active device that includes a lower vertical section, an intermediate vertical section on the lower vertical section, and an upper vertical section on the intermediate vertical section. The device isolation layer includes a first portion having a top surface and a bottom surface and in contact with the transistor and a second portion having a top surface and a bottom surface and in contact with the semiconductor structure. The lower vertical section includes an upper boundary adjacent to the intermediate vertical section, a lower surface opposite to the upper boundary, and a sidewall connecting the upper boundary and the lower surface. The sidewall of the lower vertical section is in contact with the second portion of the device isolation layer.

A semiconductor device according to some embodiments of the inventive concept may include a transistor, a first semiconductor structure spaced apart from the transistor in a first direction, and a device isolation layer surrounding the transistor and the first semiconductor structure. The transistor includes a pair of source/drain patterns adjacent to each other, a channel layer between the source/drain patterns, a gate structure on the channel layer, the first semiconductor structure includes a first lower pattern, a first intermediate pattern on the first lower pattern, and a first upper pattern on the first intermediate pattern. The device isolation layer includes a first portion in contact with the transistor and a second portion in contact with the first semiconductor structure, the source/drain patterns and the first upper pattern include impurities of a first conductivity type, the first lower pattern and the first intermediate pattern include impurities of a second conductivity type different from the first conductivity type, and a lower surface of the second portion of the device isolation layer is coplanar with a lower surface of the first lower pattern.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

FIG. 1A is a cross-sectional view of a semiconductor device according to some embodiments.

FIG. 1B is an enlarged view of region ‘E’ of FIG. 1A.

FIGS. 2A, 2B, 2C, 2D, 2E, 2F, 2G, and 2H are cross-sectional views for explaining a method of manufacturing a semiconductor device according to some embodiments.

FIG. 3 is a cross-sectional view of a semiconductor device according to some embodiments.

### DETAILED DESCRIPTION

Hereinafter, with reference to the drawings, a semiconductor device and a method of manufacturing the same according to the embodiments of the inventive concept will be described in detail.

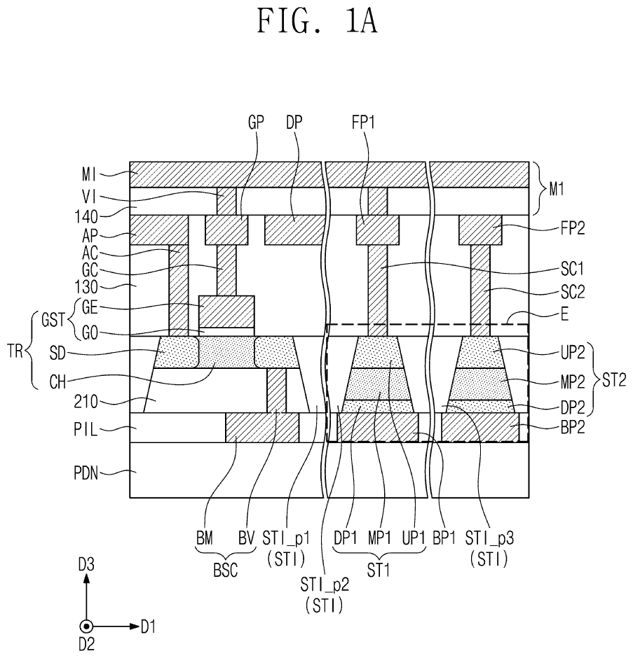

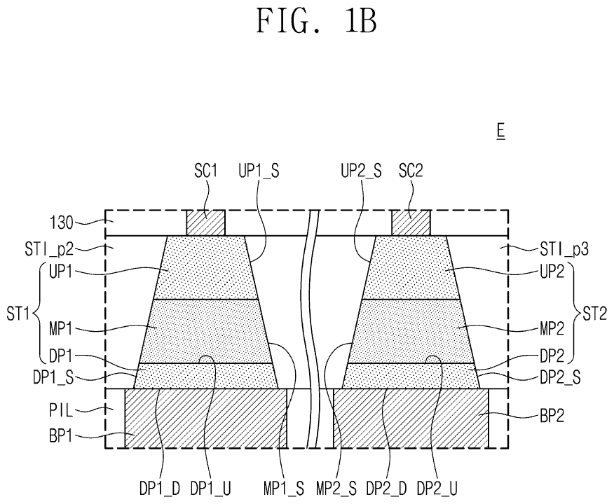

FIG. 1A is a cross-sectional view of a semiconductor device according to some embodiments. FIG. 1B is an enlarged view of region ‘E’ of FIG. 1A. A semiconductor device may be an integrated circuit including one or more transistors and other active devices, or may be an integrated circuit chip (e.g., memory chip or logic chip), formed from a wafer, that includes one or more transistors and other active devices.

Referring to FIGS. 1A and 1B, a device isolation layer STI, a transistor TR, an insulating pattern 210, a first semiconductor structure ST1, and a second semiconductor structure ST2 may be provided. The device isolation layer STI may surround the transistor TR, the insulating pattern 210, the first semiconductor structure ST1, and the second semiconductor structure ST2. The transistor TR, the first semiconductor structure ST1, and the second semiconductor structure ST2 may be spaced apart from each other in a first direction D1, with the device isolation layer STI therebetween. The transistor TR may be disposed on the insulating pattern 210. The first semiconductor structure ST1 and the second semiconductor structure ST2 may extend in a second direction D2. The first direction D1 and the second direction D2 may cross each other. For example, the first direction D1 and the second direction D2 may be horizontal directions that are orthogonal with each other. The device isolation layer STI and the insulating pattern 210 may include an insulating material. For example, the insulating pattern 210 may include oxide.

The transistor TR may include a source/drain pattern SD, a channel layer CH, and a gate structure GST. A pair of source/drain patterns SD may be included. The pair of source/drain patterns SD and the channel layer CH may be disposed on the insulating pattern 210. The channel layer CH may be disposed between the pair of source/drain patterns SD. The gate structure GST may be disposed on the channel layer CH. The gate structure GST may include a gate insulating layer GO and a gate electrode GE on the gate insulating layer GO. The transistor TR may be a field effect transistor FET. As an example, the transistor TR may be a three-dimensional field effect transistor (e.g., FinFET, MBCFET or GAAFET), but the inventive concept is not limited thereto.

The first semiconductor structure ST1 may include a first lower pattern DP1, a first intermediate pattern MP1 on the first lower pattern DP1, and a first upper pattern UP1 on the first intermediate pattern MP1. The first intermediate pattern MP1 may be in contact with or adjacent to the first lower pattern DP1 and the first upper pattern UP1. A width of each of the first lower pattern DP1, the first intermediate pattern MP1, and the first upper pattern UP1 of the first semiconductor structure ST1 in the first direction D1 may increase downwards (i.e., a width in the first direction D1 may increase from a top surface of the of the first upper pattern UP1 toward a bottom surface of the first lower pattern DP1).

The second semiconductor structure ST2 may include a second lower pattern DP2, a second intermediate pattern MP2 on the second lower pattern DP2, and a second upper pattern UP2 on the second intermediate pattern MP2. These patterns may be alternatively described as layers, or vertically stacked sections, having top and bottom boundaries therebetween. The second intermediate pattern MP2 may be in contact with or adjacent to the second lower pattern DP2 and the second upper pattern UP2. A width of each of the second lower pattern DP2, the second intermediate pattern MP2, and the second upper pattern UP2 of the second semiconductor structure ST2 in the first direction D1 may increase downwards (i.e., a width in the first direction D1 may increase from a top surface of the of the second upper pattern UP2 toward a bottom surface of the second lower pattern DP2).

In some embodiments, the first lower pattern DP1 and the second lower pattern DP2 may be epitaxial patterns. The epitaxial patterns may be patterns formed through the selective epitaxial growth process.

The device isolation layer STI may include a first portion STI_p1, a second portion STI_p2, and a third portion STI_p3. These portions may be described as horizontally separate sections. The first portion STI_p1 of the device isolation layer STI may be in contact with the transistor TR. A sidewall of the second portion STI_p2 of the device isolation layer STI may be in contact with the first semiconductor structure ST1. A sidewall of the third portion STI_p3 of the device isolation layer STI may be in contact with the second semiconductor structure ST2. A length of each of the first portion STI_p1, the second portion STI_p2, the third portion STI_p3, the first semiconductor structure ST1 and the second semiconductor structure ST2 in a third direction D3 (e.g., a height from top to bottom) may be the same as each other. The third direction D3 may cross the first direction D1 and the second direction D2. For example, the third direction D3 may be a vertical direction orthogonal with the first direction D1 and the second direction D2, which may be horizontal directions.

A back contact structure BSC may be provided below the transistor TR. The back contact structure BSC may be connected to the source/drain pattern SD of the transistor TR. In some embodiments, the back contact structure BSC may be connected to the source region of the transistor TR. The contact structure BSC may include a wiring portion BM and a via portion BV on the wiring portion BM. The wiring portion BM may be provided on a lower surface of the insulating pattern 210. The via portion BV may be connected to the source/drain pattern SD through the insulating pattern 210. The via portion BV may extend in the third direction D3. The via portion BV may connect the source/drain pattern SD and the wiring portion BM. The wiring portion BM and the via portion BV may be connected without an interface to have an integrated structure. The back contact structure BSC may be a conductive pattern formed by a dual damascene process. In some embodiments, there may be interfaces between the wiring portion BM and the via portion BV. The via portions, wiring portions, and contact structures may be formed of an electrically conductive material.

A first back conductive layer BP1 may be provided on a lower surface of the first lower pattern DP1. The first back conductive layer BP1 may be in contact with a lower surface DP1_D of the first lower pattern DP1 and a lower surface of the second portion STI_p2 of the device isolation layer STI.

A second back conductive layer BP2 may be provided on a lower surface of the second lower pattern DP2. The second back conductive layer BP2 may be in contact with a lower surface DP2_D of the second lower pattern DP2 and a lower surface of the third portion STI_p3 of the device isolation layer STI.

The back contact structure BSC, the first back conductive layer BP1, and the second back conductive layer BP2 may include a conductive material. For example, the back contact structure BSC, the first back conductive layer BP1, and the second back conductive layer BP2 may include at least one selected from the group consisting of copper (Cu), molybdenum (MO), tungsten (W), and ruthenium (Ru).

A back insulating layer PIL may be provided on a lower surface of the device isolation layer STI, a lower surface of the first semiconductor structure ST1, and a lower surface of the second semiconductor structure ST2. The back insulating layer PIL may surround the back contact structure BSC, the first back conductive layer BP1, and the second back conductive layer BP2 (e.g., in a horizontal direction). The back insulating layer PIL may be in contact with lower surfaces (e.g., bottom-most surfaces) of the first to third portions STI_p1, STI_p2, and STI_p3 of the device isolation layer STI and a lower surface (e.g., bottom-most surface) of the insulating pattern 210. The back insulating layer PIL may include an insulating material.

A power transmission network layer PDN may be provided on a lower surface of the back insulating layer PIL. The power transmission network layer PDN may include a plurality of lower wirings electrically connected to the back contact structure BSC, the first back conductive layer BP1, and the second back conductive layer BP2. As an example, the power transmission network layer PDN may include a wiring network for applying power or signal voltage to the back contact structure BSC.

A first interlayer insulating layer 130 may be provided on the device isolation layer STI, the transistor TR, the first semiconductor structure ST1, and the second semiconductor structure ST2. The first interlayer insulating layer 130 may cover the gate structure GST of the transistor TR. A second interlayer insulating layer 140 may be provided on the first interlayer insulating layer 130. Each of the first interlayer insulating layer 130 and the second interlayer insulating layer 140 may include an insulating material. As an example, the first interlayer insulating layer 130 and the second interlayer insulating layer 140 may include oxide.

An active contact AC, a gate contact GC, a first conductive contact SC1, and a second conductive contact SC2 may be provided in the first interlayer insulating layer 130. The active contact AC may be in contact with the source/drain pattern SD of the transistor TR. The gate contact GC may be in contact with the gate electrode GE of the gate structure GST. The first conductive contact SC1 may be in contact with the first upper pattern UP1 of the first semiconductor structure ST1. The second conductive contact SC2 may be in contact with the second upper pattern UP2 of the second semiconductor structure ST2. Each of the active contact AC, the gate contact GC, the first conductive contact SC1, and the second conductive contact SC2 may extend in the third direction D3 (e.g., may extend lengthwise in the third direction D3, so that a greatest length among directions D1, D2, and D3 of each contact is in the third direction D3).

An active conductive layer AP, a gate conductive layer GP, a dummy conductive layer DP, a first upper conductive layer FP1, and a second upper conductive layer FP2 may be provided in the first interlayer insulating layer 130. The active conductive layer AP may be in contact with the active contact AC. The active contact AC may penetrate the first interlayer insulating layer 130 to electrically connect the source/drain pattern SD of the transistor TR and the active conductive layer AP. The gate conductive layer GP may be in contact with the gate contact GC. The gate contact GC may penetrate the first interlayer insulating layer 130 to electrically connect the gate electrode GE and the gate conductive layer GP of the gate structure GST. Although not shown, the dummy conductive layer DP may be connected to other wiring. The dummy conductive layer DP may be floating or may be connected to wiring that does not transmit a signal or voltage therethrough during operation, or may be connected to one or more semiconductor devices that are non-operational or not used for any processing or storage tasks. The first upper conductive layer FP1 may be in contact with the first conductive contact SC1. The first conductive contact SC1 may penetrate the first interlayer insulating layer 130 and electrically connect the first upper pattern UP1 and the first upper conductive layer FP1 of the first semiconductor structure ST1. The second upper conductive layer FP2 may be in contact with the second conductive contact SC2. The second conductive contact SC2 may penetrate the first interlayer insulating layer 130 and electrically connect the second upper pattern UP2 and the second upper conductive layer FP2 of the second semiconductor structure ST2.

A metal layer M1 may be provided in the second interlayer insulating layer 140. The metal layer M1 may include wiring MI and vias VI. The wiring MI of the metal layer M1 may extend (e.g., lengthwise) in the first direction D1. Each of the vias VI may be provided under the wiring MI of the metal layer M1. The via VI may electrically connect the active conductive layer AP, the gate conductive layer GP, the dummy conductive layer DP, the first upper conductive layer FP1, or the second upper conductive layer FP2 to the wiring M1 of the metal layer M1. Although not shown, metal layers (e.g., M2, M3, M4 . . . ) stacked on the second interlayer insulating layer 140 may be additionally disposed. Each of the stacked metal layers may include wirings for routing between cells.

The active contact AC, the gate contact GC, the first conductive contact SC1, the second conductive contact SC2, the active conductive layer AP, the gate conductive layer GP, the dummy conductive layer DP, the first upper conductive layer FP1, the second upper conductive layer FP2, the wiring MI, and the via VI may include a conductive material. For example, the active contact AC, the gate contact GC, the first conductive contact SC1, the second conductive contact SC2, the active conductive layer AP, the gate conductive layer GP, the dummy conductive layer DP, the first upper conductive layer FP1, the second upper conductive layer FP2, the wiring MI, and the via VI may include at least one selected from the group consisting of copper (Cu), molybdenum (Mo), tungsten (W), and ruthenium (Ru).

A pair of source/drain patterns SD of the transistor TR may include impurities of the first conductivity type. The channel layer CH of the transistor TR may include impurities of a second conductivity type different from the first conductivity type. The first lower pattern DP1 of the first semiconductor structure ST1 may include impurities of the second conductivity type at a first concentration. The first intermediate pattern MP1 of the first semiconductor structure ST1 may include impurities of the second conductivity type at a second concentration. The first upper pattern UP1 of the first semiconductor structure ST1 may include impurities of the first conductivity type. The first semiconductor structure ST1 may have the characteristics of a diode device, and in one embodiment, may function as an active device such as a diode. The second lower pattern DP2 of the second semiconductor structure ST2 may include impurities of the second conductivity type at the first concentration. The second intermediate pattern MP2 of the second semiconductor structure ST2 may include impurities of the second conductivity type at the second concentration. The second upper pattern UP2 of the second semiconductor structure ST2 may include impurities of the second conductivity type at a third concentration. The first concentration may be greater than the second concentration. The third concentration may be greater than the second concentration. The first conductivity type may be N-type, and the second conductivity type may be P-type. In this case, the transistor TR may be an N-FET, and the second upper pattern UP2 of the second semiconductor structure ST2 may be a P-WELL. In some embodiments, the first conductivity type may be P-type and the second conductivity type may be N-type. In this case, the transistor TR may be a P-FET, and the second upper pattern UP2 of the second semiconductor structure ST2 may be an N-WELL.

The first lower pattern DP1 may include an upper surface DP1_U (e.g., top surface) or upper or top boundary, a lower surface DP1_D (e.g., bottom surface), and a sidewall DP1_S. The upper surface DP1_U or upper boundary of the first lower pattern DP1 may be in contact with or adjacent to the lower surface, or bottom boundary of the first intermediate pattern MP1. The lower surface DP1_D of the first lower pattern DP1 may be opposite to the upper surface DP1_U, or upper boundary of the first lower pattern DP1. The lower surface DP1_D of the first lower pattern DP1 may be in contact with the first back conductive layer BP1. The sidewall DP1_S of the first lower pattern DP1 may connect the upper surface DP1_U, or upper boundary, and the lower surface DP1_D of the first lower pattern DP1. The sidewall DP1_S of the first lower pattern DP1 may be in contact with the sidewall of the second portion STI_p2 of the device isolation layer STI.

The second lower pattern DP2 may include an upper surface DP2_U (e.g., top surface), or upper or top boundary, a lower surface DP2_D (e.g., bottom surface), and a sidewall DP2_S. The upper surface DP2_U or upper boundary of the second lower pattern DP2 may be in contact with the lower surface or lower boundary of the second intermediate pattern MP2. The lower surface DP2_D or lower boundary of the second lower pattern DP2 may be opposite to the upper surface DP2_U or upper boundary of the second lower pattern DP2. The lower surface DP2_D of the second lower pattern DP2 may be in contact with the second back conductive layer BP2. The sidewall DP2_S of the second lower pattern DP2 may connect the upper surface DP2_U, or upper boundary, and the lower surface DP2_D of the second lower pattern DP2. The sidewall DP2_S of the second lower pattern DP2 may be in contact with a sidewall of the third portion STI_p3 of the device isolation layer STI.

A width of the lower surface DP1_D of the first lower pattern DP1 in the first direction D1 may be greater than a width of the upper surface DP1_U or upper boundary of the first lower pattern DP1 in the first direction D1. A width of the upper surface DP1_U or upper boundary of the first lower pattern DP1 in the first direction D1 may be equal to a width of the lower surface or lower boundary of the first intermediate pattern MP1 in the first direction D1. A width of the lower surface DP1_D of the first lower pattern DP1 in the first direction D1 may be greater than a width of the lower surface or lower boundary of the first intermediate pattern MP1 in the first direction D1.

A width of the lower surface DP2_D of the second lower pattern DP2 in the first direction D1 may be greater than a width of the upper surface DP2_U or upper boundary of the second lower pattern DP2 in the first direction D1. A width of the upper surface DP2_U or upper boundary of the second lower pattern DP2 in the first direction D1 may be equal to a width of the lower surface or lower boundary of the second intermediate pattern MP2 in the first direction D1. A width of the lower surface DP2_D of the second lower pattern DP2 in the first direction D1 may be greater than a width of the lower surface or lower boundary of the second intermediate pattern MP2 in the first direction D1.

The sidewall MP1_S of the first intermediate pattern MP1 and the sidewall UP1_S of the first upper pattern UP1 may be in contact with the sidewall of the second portion STI_p2 of the device isolation layer STI. The sidewall DP1_S of the first lower pattern DP1, the sidewall MP1_S of the first intermediate pattern MP1, and the sidewall UP1_S of the first upper pattern UP1 may be coplanar.

The sidewall MP2_S of the second intermediate pattern MP2 and the sidewall UP2_S of the second upper pattern UP2 may be in contact with the sidewall of the third portion STI_p3 of the device isolation layer STI. The sidewall DP2_S of the second lower pattern DP2, the sidewall MP2_S of the second intermediate pattern MP2, and the sidewall UP2_S of the second upper pattern UP2 may be coplanar.

The lower surface DP1_D of the first lower pattern DP1 may be coplanar with the lower surface of the second portion STI_p2 of the device isolation layer STI. The lower surface DP2_D of the second lower pattern DP2 may be coplanar with the lower surface of the third portion STI_p3 of the device isolation layer STI.

A level of the upper surface DP1_U or upper boundary of the first lower pattern DP1 may be higher than a level of the lower surface of the second portion STI_p2 of the device isolation layer STI. A level of the upper surface DP1_U or upper boundary of the first lower pattern DP1 may be higher than a level of the upper surface of the back insulating layer PIL. A level of the lower surface DP1_D of the first lower pattern DP1 may be the same as a level of the lower surface of the second portion STI_p2 of the device isolation layer STI. A level of the upper surface (e.g., top surface) of the wiring portion BM of the back contact structure BSC may be the same as a level of the lower surface of the second portion STI_p2 of the device isolation layer STI. The lower surface of the second portion STI_p2 of the device isolation layer STI may be spaced apart from the first intermediate pattern MP1.

A level of the upper surface DP2_U or upper boundary of the second lower pattern DP2 may be higher than a level of the lower surface of the third portion STI_p3 of the device isolation layer STI. A level of the upper surface DP2_U or upper boundary of the second lower pattern DP2 may be higher than a level of the upper surface (e.g., top surface) of the back insulating layer PIL. A level of the lower surface DP2_D or lower boundary of the second lower pattern DP2 may be the same as a level of the lower surface of the third portion STI_p3 of the device isolation layer STI. A level of the upper surface of the wiring portion BM of the back contact structure BSC may be the same as a level of the lower surface of the third portion STI_p3 of the device isolation layer STI. The lower surface of the third portion STI_p3 of the device isolation layer STI may be spaced apart from the second intermediate pattern MP2.

The sidewall DP1_S of the first lower pattern DP1 may be inclined with respect to the lower surface DP1_D of the first lower pattern DP1. For example, an angle between the sidewall DP1_S and the lower surface DP1_D of the first lower pattern DP1 may be greater than 0 degrees and less than 90 degrees. The sidewall DP2_S of the second lower pattern DP2 may be inclined with respect to the lower surface DP2_D of the second lower pattern DP2. For example, an angle between the sidewall DP2_S and the lower surface DP2_D of the second lower pattern DP2 may be greater than 0 degrees and less than 90 degrees.

The semiconductor device according to some embodiments may include the lower patterns DP1 and DP2 connecting the semiconductor structures ST1 and ST2 to the back conductive layers BP1 and BP2. As the semiconductor structures ST1 and ST2 include the lower patterns DP1 and DP2, the semiconductor structures ST1 and ST2 may be electrically connected to the wirings. Accordingly, even though a bulkless structure with the substrate removed is provided, the semiconductor device may not include a floating well structure, and thus device distribution and reliability of the semiconductor device may be secured.

Although only one transistor TR and two semiconductor structures ST1 and ST2 are shown, a plurality of additional such devices may be included.

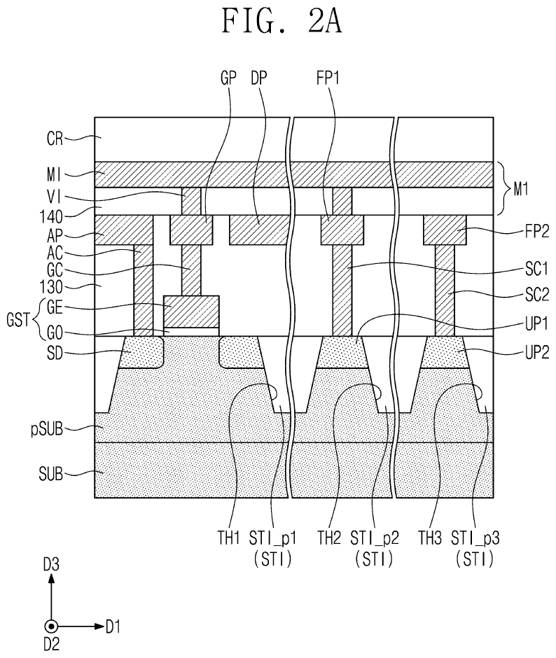

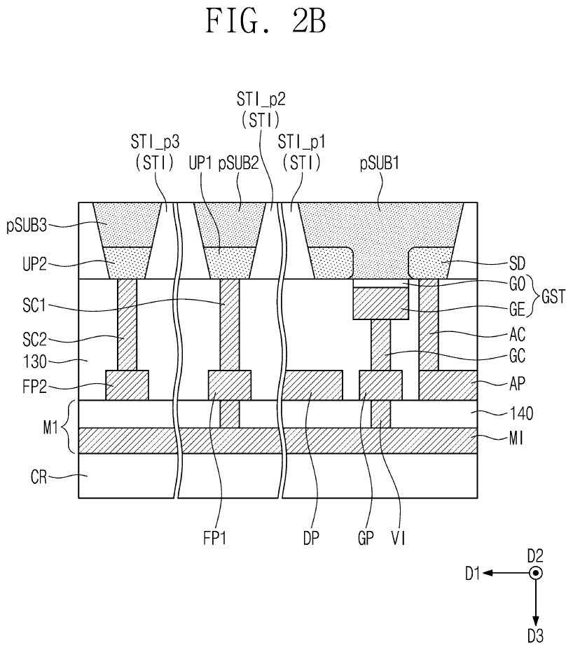

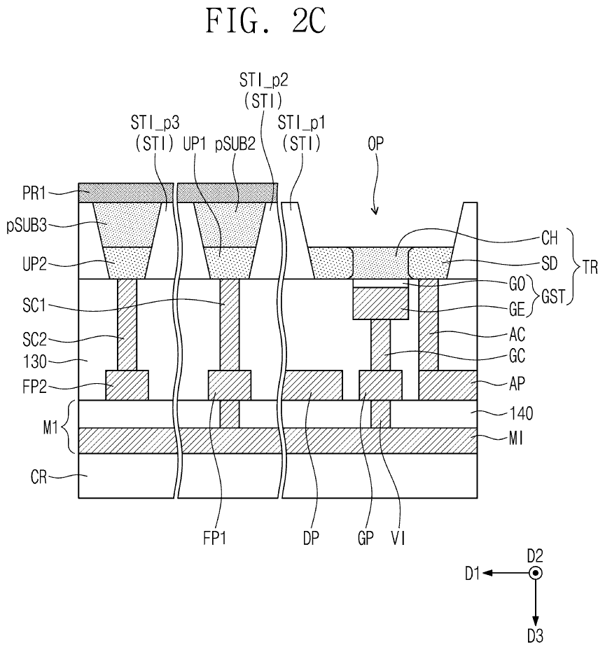

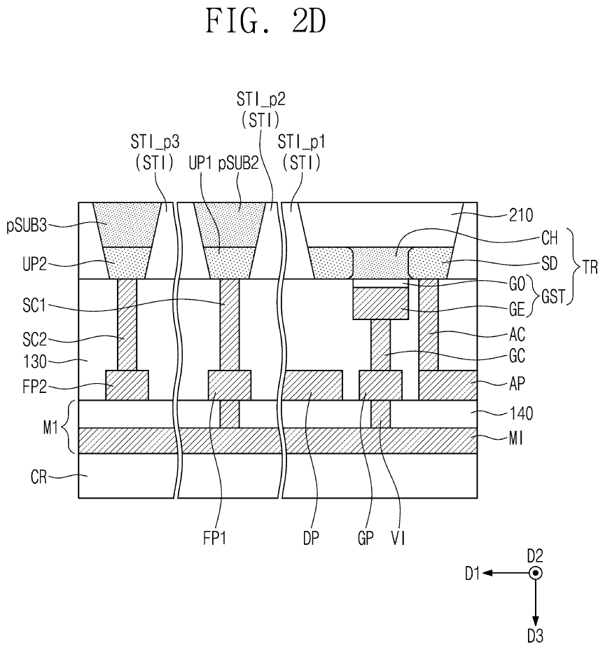

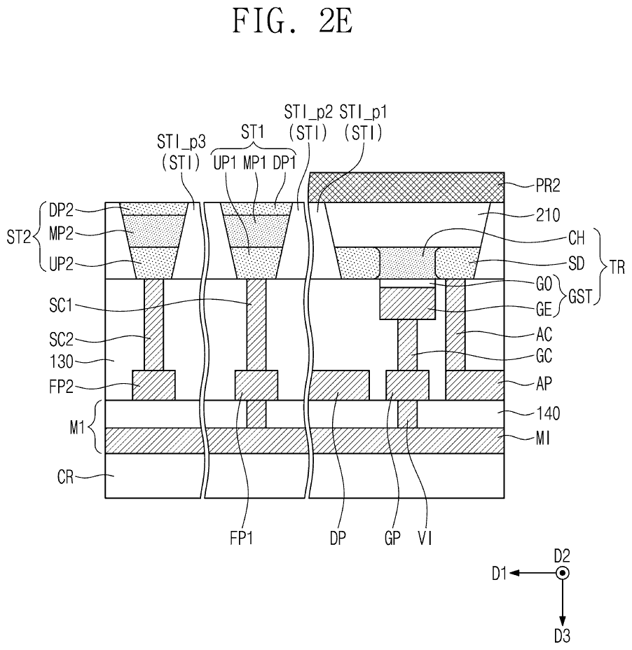

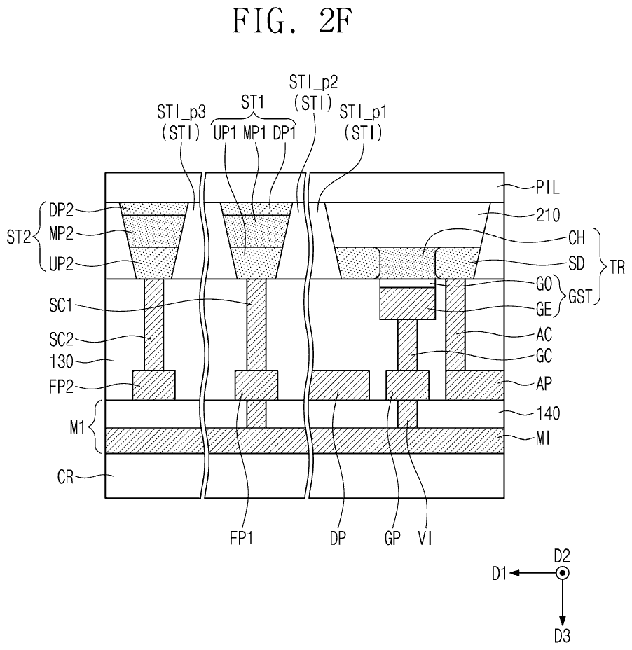

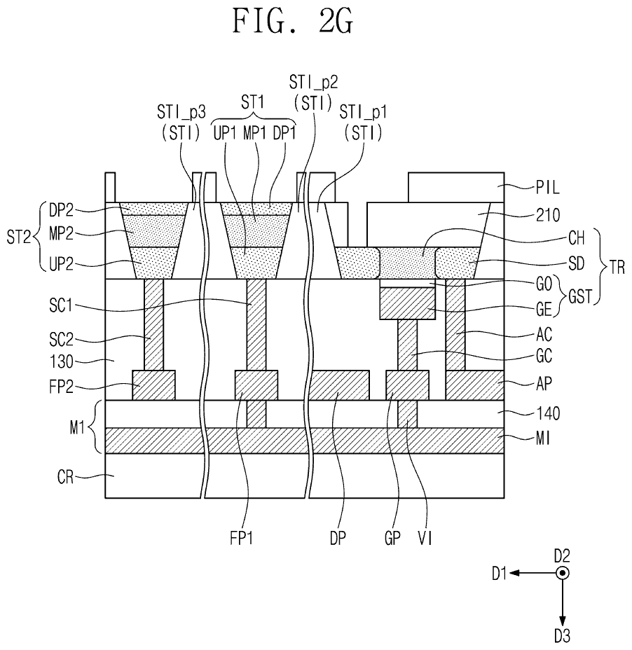

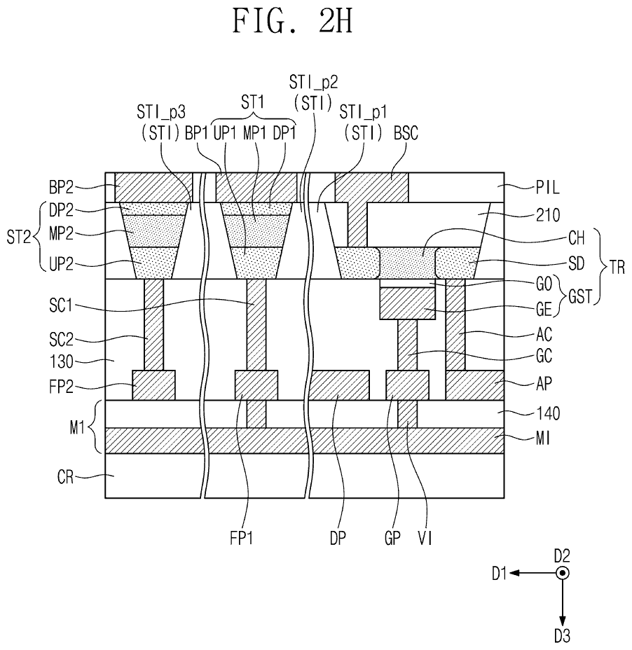

FIGS. 2A, 2B, 2C, 2D, 2E, 2F, 2G, and 2H are cross-sectional views for explaining a method of manufacturing a semiconductor device according to some embodiments. FIGS. 2A to 2H may correspond to FIG. 1A.

Referring to FIG. 2A, a substrate SUB and a doped pattern pSUB on the substrate SUB are formed. The doped pattern pSUB may be a portion formed by doping impurities on an upper portion of the substrate SUB. The substrate SUB and the doped pattern pSUB may include impurities of a second conductivity type. Impurities of the second conductivity type may be doped on the upper portion of the substrate SUB so that an impurity concentration of the doped pattern pSUB is higher than that of the substrate SUB.

A device isolation layer STI may be formed on the doped pattern pSUB. The doped pattern pSUB may include trenches TH1, TH2, and TH3. The trenches TH1, TH2, and TH3 may include a first trench TH1, a second trench TH2, and a third trench TH3. The first to third trenches TH1, TH2, and TH3 may be defined by a surface of the doped pattern pSUB. The device isolation layer STI may fill the trenches TH1, TH2, and TH3. A first portion STI_p1 of the device isolation layer STI may be provided on the first trench TH1. A second portion STI_p2 of the device isolation layer STI may be provided on the second trench TH2. A third portion STI_p3 of the device isolation layer STI may be provided on the third trench TH3.

The substrate SUB may be a semiconductor substrate. As an example, the substrate SUB may include silicon, germanium, silicon-germanium, GaP, or GaAs. For example, the substrate SUB may include poly silicon. In some embodiments, the substrate SUB may be a silicon-on-insulator (SOI) substrate or a germanium-on-insulator (GOI) substrate.

Impurities may be doped on the doped pattern pSUB to form source/drain patterns SD, a first upper pattern UP1, and a second upper pattern UP2. The source/drain patterns SD and the first upper pattern UP1 may be formed by doping the doped pattern pSUB with impurities of a first conductivity type. The second upper pattern UP2 may be formed by doping the doped pattern pSUB with impurities of a second conductivity type. The substrate SUB may be doped with impurities of the second conductivity type so that an impurity concentration of the second upper pattern UP2 is higher than an impurity concentration of the doped pattern pSUB. A boundary between the doped pattern pSUB and each of the source/drain patterns SD, a first upper pattern UP1, and a second upper pattern UP2 may be based on a doping concentration of impurities doped to form the source/drain patterns SD, first upper pattern UP1, and second upper pattern UP2. For example, a location where the impurity concentration from that doping drops below a particular level (e.g., below a level that would allow the newly created pattern to perform as an active region) may comprise a boundary between the two sections. The “surfaces” of the lower, upper, and intermediate patterns described herein may be boundaries, delineated based on amount of doping concentration.

A gate structure GST may be formed on the doped pattern pSUB. The gate structure GST may be formed on the upper surface of the doped pattern pSUB exposed between a pair of adjacent source/drain patterns SD.

A first interlayer insulating layer 130 covering the gate structure GST may be formed. In the first interlayer insulating layer 130, an active contact AC, a gate contact GC, a first conductive contact SC1, a second conductive contact SC2, an active conductive layer AP, a gate conductive layer GP, a dummy conductive layer DP, a first upper conductive layer FP1, and a second upper conductive layer FP2 may be formed. The active contact AC may be formed on the source/drain pattern SD. The gate contact GC may be formed on gate structure GST. The first conductive contact SC1 may be formed on the first upper pattern UP1. The second conductive contact SC2 may be formed on the second upper pattern UP2. The active conductive layer AP may be formed on the active contact AC. The gate conductive layer GP may be formed on the gate contact GC. The first upper conductive layer FP1 may be formed on the first conductive contact SC1. The second upper conductive layer FP2 may be formed on the second conductive contact SC2.

A second interlayer insulating layer 140 and a metal layer M1 may be formed on the first interlayer insulating layer 130. The metal layer M1 may be formed in the second interlayer insulating layer 140.

A carrier substrate CR may be formed on the metal layer M1. The carrier substrate CR may be provided on the second interlayer insulating layer 140. The carrier substrate CR may be attached to the second interlayer insulating layer 140 to perform a process on the lower surface of the substrate SUB in a manufacturing method described later. In some embodiments, an insulating layer containing nitride may be provided between the carrier substrate CR and the second interlayer insulating layer 140.

Referring to FIG. 2B, the semiconductor device being manufactured is turned over. Accordingly, the upper surface of the substrate SUB may be exposed. The upper portion of the substrate SUB and doped pattern pSUB are then removed. In some embodiments, the upper portion of the substrate SUB and the doped pattern pSUB may be removed by a chemical mechanical polishing (CMP) process. The upper portion of the doped pattern pSUB may be removed to form a first preliminary pattern pSUB1 on the gate structure GST, a second preliminary pattern pSUB2 on the first upper pattern UP1, and a third preliminary pattern pSUB3 on the second upper pattern UP2. The first preliminary pattern pSUB1, the second preliminary pattern pSUB2, and the third preliminary pattern pSUB3 may be the remaining portions of the doped pattern pSUB remaining after the upper portion of the doped pattern pSUB is removed.

The upper portion of the doped pattern pSUB may be removed until the device isolation layer STI is exposed. The upper portion of the doped pattern pSUB may be removed to expose the upper surfaces of the first to third portions STI_p1, STI_p2, and STI_p3 of the device isolation layer STI. The upper surfaces of the first to third portions STI_p1, STI_p2, and STI_p3 of the device isolation layer STI may serve as an etch stop layer. As the upper portion of the substrate SUB is removed, the semiconductor device may include a bulkless structure in which the first to third preliminary patterns pSUB1, pSUB2, and pSUB3 are separated by the first to third portions STI_p1, STI_p2, and STI_p3 of the device isolation layer STI. In a bulkless structure, a continuous semiconductor substrate having an uninterrupted plate shape is not included, as can be seen in FIGS. 1A and 2B.

Referring to FIG. 2C, a mask pattern PR1 is formed on the second portion STI_p2 of the device isolation layer STI, the third portion STI_p3 of the device isolation layer STI, the second preliminary pattern pSUB2, and the third preliminary pattern pSUB3. A portion of the first preliminary pattern pSUB1 is removed. When the portion of the first preliminary pattern pSUB1 is removed, the mask pattern PR1 may protect the second portion STI_p2 of the device isolation layer STI, the third portion STI_p3 of the device isolation layer STI, the second preliminary pattern pSUB2, and the third preliminary pattern pSUB3. The mask pattern PR1 may include a material that has an etch selectivity with respect to that of the first preliminary pattern pSUB1.

The portion of the first preliminary pattern pSUB1 may be removed to expose a sidewall of the first portion STI_p1 of the device isolation layer STI and a surface of the source/drain pattern SD. The portion of the first preliminary pattern pSUB1 may be removed to form the channel layer CH. The first preliminary pattern pSUB1 that remains after a portion has been removed may be the channel layer CH. The channel layer CH may be formed as part of a transistor TR. The portion of the first preliminary pattern pSUB1 may be removed to form an opening op. As the portion of the first preliminary pattern pSUB1 is removed, the exposed sidewall of the first portion STI_p1 of the device isolation layer STI, surface of the source/drain pattern SD, and surface of the channel layer CH may define the opening op. In some embodiments, the portion of the first preliminary pattern pSUB1 may be removed through a dry etch process.

Referring to FIG. 2D, the mask pattern PR1 is removed. After removing the mask pattern PR1, an insulating pattern 210 is formed on the transistor TR. The insulating pattern 210 may be formed in the opening op. The insulating pattern 210 may entirely fill the opening op.

Referring to FIG. 2E, a blocking pattern PR2 is formed on the insulating pattern 210 and the first portion STI_p1 of the device isolation layer STI. The blocking pattern PR2 may protect the insulating pattern 210 and the first portion STI_p1 of the device isolation layer STI when impurities are injected into the second preliminary pattern pSUB2 and the third preliminary pattern pSUB3.

The impurities may be doped on an upper portion of the second preliminary pattern pSUB2 to form a first semiconductor structure ST1. The impurities may be doped on an upper portion of the third preliminary pattern pSUB3 to form a second semiconductor structure ST2. Impurities of a second conductivity type may be doped on each of the upper portions of the second preliminary pattern pSUB2 and the third preliminary pattern pSUB3 to form a first lower pattern DP1 of the first semiconductor structure ST1 and a second lower pattern DP2 of the second semiconductor structure ST2. The second preliminary pattern pSUB2 may be doped with the impurities of a second conductivity type so that an impurity concentration of the first lower pattern DP1 is higher than an impurity concentration of the second preliminary pattern pSUB2. The second preliminary pattern pSUB2 may be doped with impurities of a second conductivity type so that an impurity concentration of the second lower pattern DP2 is higher than an impurity concentration of the third preliminary pattern pSUB3. A boundary between the second preliminary pattern pSUB2 and each of the first lower pattern DP1, and the second lower pattern DP2 may be based on a doping concentration of impurities doped to form the first lower pattern DP1, and the second lower pattern DP2. For example, a location where the impurity concentration from that doping drops below a particular level (e.g., below a level that would allow the newly created pattern to perform its intended function) may comprise a boundary between the two sections,

In some embodiments, doping impurities on an upper portion of the second preliminary pattern pSUB2 and an upper portion of the third preliminary pattern pSUB3 may be performed by an ion implantation process.

Referring to FIG. 2F, the blocking pattern PR2 is removed. After removing the blocking pattern PR2, a back insulating layer PIL is formed on the device isolation layer STI, the insulating pattern 210, the first semiconductor structure ST1, and the second semiconductor structure ST2. The back insulating layer PIL may conformally cover an upper surfaces of the device isolation layer STI, the insulating pattern 210, the first semiconductor structure ST1, and the second semiconductor structure ST2.

Referring to FIG. 2G, a portion of the back insulating layer PIL and a portion of the insulating pattern 210 are removed. The portion of the back insulating layer PIL and the portion of the insulating pattern 210 may be removed to expose the source/drain pattern SD of the transistor TR, the first lower pattern DP1 of the first semiconductor structure ST1, and the second lower pattern DP2 of the second semiconductor structure ST2. Removing the portion of the back insulating layer PIL and the portion of the insulating pattern 210 may include forming a photoresist layer (not shown) on the back insulating layer PIL, forming a hole by removing a photoresist layer (not shown) through a photolithography process, and etching the back insulating layer PIL and the insulating pattern 210 using a photoresist layer (not shown) as an etch mask. In some embodiments, etching the back insulating layer PIL and the insulating pattern 210 may be performed through a dry etch process.

Referring to FIG. 2H, a back contact structure BSC, a first back conductive layer BP1, and a second back conductive layer BP2 are formed. Empty spaces formed by removing the portion of the back insulating layer PIL and the portion of the insulating pattern 210 may be filled with a conductive pattern to form the first back conductive layer BP1 and the second back conductive layer BP2. In some embodiments, the back contact structure BSC may be formed by a dual damascene process.

Referring again to FIG. 1A, a power transmission network layer PDN may be formed on the back insulating layer PIL. Although not shown, bumps (not shown) may be formed on the power transmission network layer PDN. A semiconductor device, such as a semiconductor chip on which the first semiconductor structure ST1, the second semiconductor structure ST2, and the transistor TR are formed, may be electrically connected to an external device through a bump (not shown). To connect the bump (not shown) to an external device, the semiconductor device may be turned over again.

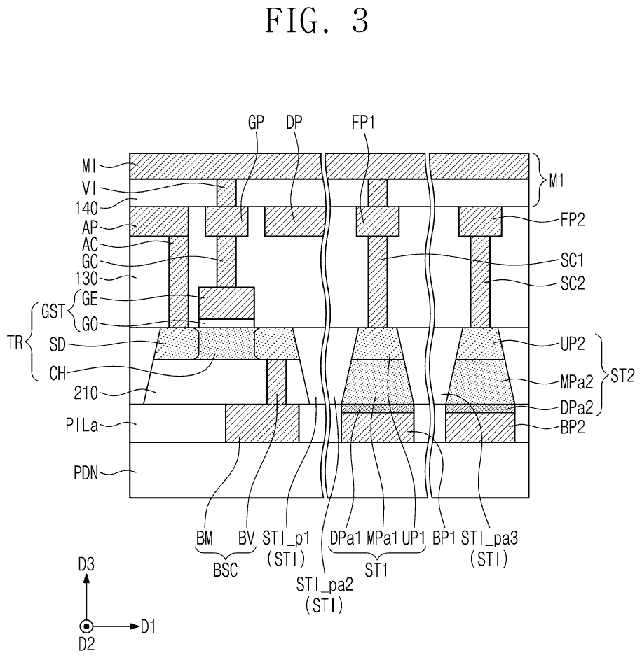

FIG. 3 is a cross-sectional view of a semiconductor device according to some embodiments. The semiconductor device according to FIG. 3 may be similar to the semiconductor device according to FIGS. 1A and 1B, except as described below.

Referring to FIG. 3, a first lower pattern DPa1 on a lower surface of a first intermediate pattern MPa1 of the first semiconductor structure ST1 and a second lower pattern Dpa2 on a lower surface of a second intermediate pattern MPa2 of the second semiconductor structure ST2 may be provided.

A width of a lower surface of the first intermediate pattern MPa1 in the first direction D1 may be equal to a width of a lower surface of the first lower pattern DPa1 in the first direction D1. A sidewall of the first lower pattern DPa1 may be in contact with a back insulating layer PILa. A level of the lower surface of the first lower pattern DPa1 may be lower than a level of the lower surface of the second portion STI_pa2 of the device isolation layer STI. A level of the upper surface of the first lower pattern DPa1 may be the same as a level of the lower surface of the second portion STI_pa2 of the device isolation layer STI. The lower surface of the first intermediate pattern MPa1 may be coplanar with the lower surface of the second portion STI_pa2 of the device isolation layer STI.

A width of the lower surface of the second intermediate pattern MPa2 in the first direction D1 may be equal to a width of the lower surface of the second lower pattern DPa2 in the first direction D1. A sidewall of the second lower pattern DPa2 may be in contact with a back insulating layer PILa. A level of the lower surface of the second lower pattern DPa2 may be lower than a level of the lower surface of the third portion STI_pa3 of the device isolation layer STI. A level of the upper surface of the second lower pattern DPa2 may be the same as a level of the lower surface of the third portion STI_pa3 of the device isolation layer STI. The lower surface of the second intermediate pattern MPa2 may be coplanar with the lower surface of the third portion STI_pa3 of the device isolation layer STI.

The first lower pattern DPa1 and the second lower pattern DPa2 may be epitaxial patterns formed through a selective epitaxial growth process. The first lower pattern DPa1 and the second lower pattern DPa2 may include a single crystal semiconductor material. As an example, the first lower pattern DPa1 and the second lower pattern DPa2 may include single crystal silicon.

In the semiconductor device according to embodiments of the inventive concept, as the semiconductor structure includes the lower pattern connected to the back conductive layer, the semiconductor structure may be electrically connected to wirings. Accordingly, although the bulkless structure with the substrate removed is provided, the floating well structure may not be provided and the device distribution and reliability of the semiconductor device may be secured.

While embodiments are described above, a person skilled in the art may understand that many modifications and variations are made without departing from the spirit and scope of the invention defined in the following claims. Accordingly, the example embodiments of the inventive concept should be considered in all respects as illustrative and not restrictive.

What is claimed is:

1. A semiconductor device comprising:
a transistor;
a semiconductor structure spaced apart from the transistor in a first direction;
a device isolation layer surrounding the transistor and the semiconductor structure,
wherein the semiconductor structure comprises an active device that includes a lower pattern, an intermediate pattern on the lower pattern, and an upper pattern on the intermediate pattern,
wherein the device isolation layer includes a first portion having a top surface and a bottom surface and being in contact with the transistor, and a second portion having a top surface and a bottom surface and being in contact with the semiconductor structure, and
wherein a level of a top boundary of the lower pattern is higher than a level of the bottom surface of the second portion of the device isolation layer.

2. The semiconductor device of claim 1, wherein a width of a bottom surface of the lower pattern in the first direction is greater than a width of the top boundary of the lower pattern in the first direction.

3. The semiconductor device of claim 2, wherein the lower pattern further includes a sidewall connecting the top boundary of the lower pattern and the bottom surface of the lower pattern, and
wherein the sidewall of the lower pattern is in contact with the second portion of the device isolation layer.

4. The semiconductor device of claim 1, further comprising a back contact structure connected to the transistor,
wherein the back contact structure includes a wiring portion and a via portion on the wiring portion,
wherein a top surface of the via portion is in contact with the transistor, and
wherein a vertical level of a top surface of the wiring portion is equal to a vertical level of the bottom surface of the second portion of the device isolation layer.

5. The semiconductor device of claim 1, wherein the transistor includes:
a pair of source/drain patterns adjacent to each other;
a channel layer between the source/drain patterns; and
a gate structure on the channel layer,
wherein the source/drain patterns include impurities of a first conductivity type,
wherein the lower pattern includes impurities of a second conductivity type different from the first conductivity type at a first concentration,
wherein the intermediate pattern includes impurities of the second conductivity type at a second concentration,
wherein the first concentration is greater than the second concentration, and
wherein a sidewall of the lower pattern is coplanar with a sidewall of the intermediate pattern.

6. The semiconductor device of claim 5, wherein the upper pattern includes impurities of the first conductivity type.

7. The semiconductor device of claim 5, wherein the upper pattern includes impurities of the second conductivity type at a third concentration, and
wherein the third concentration is greater than the second concentration.

8. The semiconductor device of claim 1, further comprising:
a back conductive layer in contact with a bottom surface of the lower pattern; and
a back insulating layer surrounding the back conductive layer,
wherein the back insulating layer is in contact with the bottom surface of the second portion of the device isolation layer.

9. The semiconductor device of claim 8, wherein the back conductive layer is in contact with the second portion of the device isolation layer.

10. The semiconductor device of claim 1, wherein the intermediate pattern is spaced apart from the bottom surface of the second portion of the device isolation layer.

11. The semiconductor device of claim 1, wherein the lower pattern is an epitaxial pattern.

12. The semiconductor device of claim 1, wherein a width of the top boundary of the lower pattern is equal to a width of a boundary of the intermediate pattern.

13. A semiconductor device comprising:
a transistor;
a semiconductor structure spaced apart from the transistor in a horizontal direction; and
a device isolation layer surrounding the transistor and the semiconductor structure,
wherein the semiconductor structure comprises an active device that includes a lower vertical section, an intermediate vertical section on the lower vertical section, and an upper vertical section on the intermediate vertical section,
wherein the device isolation layer includes a first portion having a top surface and a bottom surface and in contact with the transistor and a second portion having a top surface and a bottom surface and in contact with the semiconductor structure,
wherein the lower vertical section includes:
an upper boundary adjacent to the intermediate vertical section,
a lower surface opposite to the upper boundary, and
a sidewall connecting the upper boundary and the lower surface, and
wherein the sidewall of the lower vertical section is in contact with the second portion of the device isolation layer.

14. The semiconductor device of claim 13, wherein a sidewall of the intermediate vertical section is in contact with the second portion of the device isolation layer, and
wherein a level of the bottom surface of the second portion of the device isolation layer is lower than a level of the upper boundary of the lower vertical section.

15. The semiconductor device of claim 13, wherein the sidewall of the lower vertical section is inclined with respect to the lower surface of the lower vertical section.

16. The semiconductor device of claim 13, wherein a width of the lower vertical section in the first direction increases in a direction away from the intermediate vertical section.

17. The semiconductor device of claim 13, wherein a sidewall of the upper vertical section is in contact with the second portion of the device isolation layer, and
wherein a level of the lower surface of the lower vertical section is equal to a level of the bottom surface of the second portion of the device isolation layer.

18. A semiconductor device comprising:
a transistor;
a first semiconductor structure spaced apart from the transistor in a first direction; and
a device isolation layer surrounding the transistor and the first semiconductor structure,
wherein the transistor includes:
a pair of source/drain patterns adjacent to each other;
a channel layer between the source/drain patterns;
a gate structure on the channel layer,
wherein the first semiconductor structure includes a first lower pattern, a first intermediate pattern on the first lower pattern, and a first upper pattern on the first intermediate pattern,
wherein the device isolation layer includes a first portion in contact with the transistor and a second portion in contact with the first semiconductor structure,
wherein the source/drain patterns and the first upper pattern include impurities of a first conductivity type,
wherein the first lower pattern and the first intermediate pattern include impurities of a second conductivity type different from the first conductivity type, and
wherein a lower surface of the second portion of the device isolation layer is coplanar with a lower surface of the first lower pattern.

19. The semiconductor device of claim 18, further comprising a second semiconductor structure spaced apart from the first semiconductor structure in the first direction,
wherein the device isolation layer further includes a third portion in contact with the second semiconductor structure,
wherein the second semiconductor structure includes a second lower pattern, a second intermediate pattern on the second lower pattern, and a second upper pattern on the second intermediate pattern,
wherein the second lower pattern, the second intermediate pattern, and the second upper pattern include impurities of the second conductivity type, and
wherein the lower surface of the first lower pattern is coplanar with a lower surface of the second lower pattern.

20. The semiconductor device of claim 19, further comprising:
a first back conductive layer in contact with the lower surface of the first lower pattern; and
a second back conductive layer in contact with the lower surface of the second lower pattern,
wherein the first back conductive layer is in contact with the second portion of the device isolation layer, and
wherein the second back conductive layer is in contact with the third portion of the device isolation layer.
